(19) United States
(12) Patent Application Publication
(10) Pub. No.: US 2024/0302136 A1
(43) Pub. Date: Sep. 12, 2024

(54) ARTICULATING MODULAR NIGHT VISION DEVICE

(71) Applicant: WILCOX INDUSTRIES CORP., Newington, NH (US)

(72) Inventors: James W. Teetzel, Portsmouth, NH (US); Gary M. Lemire, Lee, NH (US)

(21) Appl. No.: 18/590,352

(22) Filed: Feb. 28, 2024

Related U.S. Application Data
(60) Provisional application No. 63/450,799, filed on Mar. 8, 2023.

(51) Int. Cl. F41G 11/00; F41G 1/38; G02B 23/12; H01R 12/65; H05K 1/02

(52) U.S. Cl. CPC F41G 11/003; F41G 1/38; G02B 23/12; H01R 12/65; H05K 1/028; H05K 2201/056

(57) ABSTRACT

An articulating, modular night vision assembly includes a powered bridge assembly with a center base section and left and right pivoting arms, each detachably receiving a night vision monocular assembly. The night vision monocular assemblies include a weapon hot shoe for mounting to a weapon accessory interface. In a further aspect, a powered bridge assembly is provided.

### CROSS REFERENCE TO RELATED APPLICATION

This application claims the priority benefit of U.S. provisional application no. 63/450,799 filed Mar. 8, 2023. The aforementioned application is incorporated herein by reference in its entirety.

### BACKGROUND

The present invention relates generally to night vision devices and, in particular, to a modular binocular night vision system comprising a pair of night vision monoculars and a powered mounting bridge.

Commonly, night vision devices used by aviators lack an internal power supply or battery compartment and, instead, are typically powered by an external power supply, such as a battery pack electrically coupled to the night vision device through a cable connection, or in some cases using the electrical system of the aircraft. The use of an external power supply provides a consistent source of power and improves safety since it eliminates the risk that an internal battery power source may become depleted during a long flight. In addition, omitting an internal battery in the night vision device reduces the size and weight of the night vision device, thereby improving comfort when worn for long periods. Furthermore, aviator night vision devices also often have a relatively wide field of view to allow for greater situational awareness during flight than a ground force style night vision device.

On the other hand, night vision devices used by ground forces typically have a battery compartment with an internal battery as the power supply. This allows the night vision device to operate independently from an external power source. This provides ground forces operating at night or in low light areas with greater mobility and the ability to operate in environments where an external power source is not available. In addition, night vision devices used by ground forces tend to have a narrower field of view than those used by aviators to allow for better target identification and tracking.

Another difference between aviator style night vision devices and night vision devices used by ground forces is that ground forces need the ability to quickly transition between using their night vision devices and operating without them, while aviators generally use their night vision devices for extended periods, e.g., for the duration of a flight. Therefore, designs for aviator style night vision devices typically have not prioritized the ability to stow the night vision devices on the helmet when not in use.

The present disclosure contemplates a new and improved night vision apparatus and method which combines the size and weight advantages of aviator style night vision devices and the increased mobility and stowability of night vision devices typically used by ground forces. The present disclosure also contemplates an improved night vision apparatus and method having the ability to adjust the horizontal field of view between a relatively narrow horizontal field of view, e.g., for targeting and target identification, and one or more wider horizontal fields of view, e.g., for enhanced situational awareness.

### SUMMARY

In one aspect, a monocular assembly comprises a housing having an interior and an objective lens assembly coupled to a distal end of the housing. An eyepiece assembly is coupled to a proximal end of the housing and an image intensifier tube is disposed within the housing. A power contact circuit board flex assembly is disposed within the housing. The power contact circuit board flex assembly comprises a flexible circuit board and a first plurality of power contacts in electrical communication with the flexible circuit board and disposed at a first angular position on the housing. A second plurality of power contacts are in electrical communication with the flexible circuit board and disposed at a second angular position on the housing. A third plurality of power contacts are in electrical communication with the flexible circuit board and disposed at a third angular position on the housing. Each of the first, second, and third plurality of power contacts are in electrical communication with the image intensifier tube. The flexible circuit board extends around the image intensifier tube within the interior of the housing.

In a more limited aspect, the monocular assembly further comprises a lower power contact cover with at a plurality of openings through which the third plurality of power contacts extend.

In another more limited aspect, the monocular assembly further comprises an opening in the housing and a pivot assembly covering the opening in the housing opening. The pivot assembly comprises a lower pivot plate affixed to the housing and an upper pivot plate secured to the lower pivot plate, the upper pivot plate rotatable in relation to the lower pivot plate.

In another more limited aspect, the lower pivot plate comprises a plurality of detent slots and the upper pivot plate comprises at least one detent pillar positioned and sized to be caught by any of the plurality of detent slots such that the rotation of the upper pivot plate is stopped at the catching of the at least one detent pillar by one of the plurality of detent slots.

In another more limited aspect, the plurality of detent slots includes five detent slots spaced apart by 6 degrees of rotation, allowing selective angular positioning of the upper pivot plate with relation to the lower pivot plate at an angle of negative 12 degrees, negative 6 degrees, 0 degrees, positive 6 degrees, and positive 12 degrees.

In another more limited aspect, wherein the first plurality of power contacts comprise positive and negative power contacts each of which extend through an aligned power contact opening in the lower pivot plate and aligned power contact opening in the upper pivot plate.

In another more limited aspect, wherein the aligned power contact openings in the lower pivot plate define curved slots in which individual ones of the first plurality of power contacts run during rotational movement between the upper and lower pivot plates.

In another more limited aspect, the monocular assembly further comprises a pivot assembly mounting boss extending from the housing and surrounding the opening in the housing, wherein the lower pivot plate is affixed to the pivot assembly mounting boss.

In another more limited aspect, the monocular assembly further comprises a weapon hot shoe disposed at the second angular position on the housing, the weapon hot shoe having a weapon hot shoe plate portion. A plurality of bores extend through the weapon hot shoe and a plurality of power contact pins are received within the plurality of bores. The plurality of power contact pins are in electrical communication with the second plurality of power contacts and protrude from the weapon hot shoe plate portion.

In another more limited aspect, the monocular assembly further comprises a weapon hot shoe disposed at the second angular position on the housing, the weapon hot shoe having a weapon hot shoe plate portion. A plurality of bores extend through the weapon hot shoe and a plurality of power contact pins are received within the plurality of bores. The plurality of power contact pins are in electrical communication with the second plurality of power contacts and protruding from the weapon hot shoe plate portion.

In another more limited aspect, the weapon hot shoe assembly further comprises a weapon hot shoe boss extending from the housing and wherein the weapon hot shoe plate is affixed to the weapon hot shoe boss.

In another more limited aspect, the monocular assembly further comprises a powered weapon mount comprising a powered weapon mount base having a rail clamp for detachable engagement with a weapon rail. An accessory interface is pivotally attached to the powered weapon mount base via a hinge assembly. The accessory interface comprises a shoe receiver designed for mechanical releasable communication with the weapon hot shoe plate of the weapon hot shoe assembly. A plurality of receiver power contacts are in electrical communication with the second plurality of power contact pins when the shoe receiver and the weapon hot shoe plate are paired.

In another more limited aspect, the monocular assembly further comprises a lower circuit board secured to the housing at the third angular position, the lower circuit board having said third plurality of power contacts thereon.

In another more limited aspect, the monocular assembly further comprises a lower contact boss disposed on the housing at the third angular position, the lower contact boss defining a lower opening into the housing, the lower contact boss and longitudinally extending protrusions formed on opposing sides of the lower contact boss. A lower power contact cover covers the lower opening, the lower power contact cover having a plurality of apertures receiving the third plurality of power contacts therethrough.

In another more limited aspect, the monocular assembly further comprises a lower contact boss having longitudinally extending interlocking protrusions formed on opposing sides thereof. A blanking cover has a pair of opposing longitudinally extending interlocking recesses that slidably engage with the longitudinally extending interlocking protrusions, the blanking cover configured to cover the third plurality of power contacts.

In a further aspect, a powered bridge assembly comprises a center base section having a hot shoe power interface operable to detachably couple to a helmet mount assembly. A first plurality of electrical power contacts are disposed within the center base section and electrically coupled to a second plurality of electrical power contacts disposed within the center base section. The first plurality of electrical contacts are configured to receive power from the helmet mount assembly. A first pivoting bridge member includes a first slide lock assembly for detachably coupling a first monocular assembly, the first pivoting bridge member pivotable between a deployed position and a stowed position. A first hinge assembly pivotally couples the first pivoting bridge member to the center base section. A third plurality of electrical power contacts are disposed within the first pivoting bridge member, wherein the second plurality of electrical power contacts is operable to electrically couple the first plurality of electrical power contacts to the third plurality of electrical power contacts when the first pivoting bridge member is in the deployed position and further wherein the second plurality of electrical power contacts is configured to be electrically isolated from the third plurality of electrical contacts when the first pivoting bridge member is in the stowed position.

In more limited aspect, the first monocular assembly is detachably coupled to the first pivoting bridge member, the first monocular assembly comprising a housing having an interior and an objective lens assembly coupled to a distal end of the housing. An eyepiece assembly is coupled to a proximal end of the housing and an image intensifier tube is disposed within the housing. A power contact circuit board flex assembly is disposed within the housing, the power contact circuit board flex assembly comprising a flexible circuit board. A fourth plurality of power contacts are in electrical communication with the flexible circuit board and disposed at a first angular position on the housing. A fifth plurality of power contacts are in electrical communication with the flexible circuit board and disposed at a second angular position on the housing. A sixth plurality of power contacts are in electrical communication with the flexible circuit board and disposed at a third angular position on the housing. Each of the fourth, fifth, and sixth plurality of power contacts are in electrical communication with the image intensifier tube, wherein the flexible circuit board extends around the image intensifier tube within the interior of the housing.

In another more limited aspect, the monocular assembly further comprises an opening in the housing and a pivot assembly covers the opening in the housing opening. The pivot assembly includes a lower pivot plate affixed to the housing and an upper pivot plate secured to the lower pivot plate, the upper pivot plate rotatable in relation to the lower pivot plate.

In another more limited aspect, the first pivoting bridge member includes a slide lock assembly structured and operable to releasably couple with the upper pivot plate of the first monocular assembly.

In another more limited aspect, the powered bridge assembly further comprises a second pivoting bridge member, the second pivoting bridge member including a second slide lock assembly for detachably coupling a second monocular assembly, wherein the first pivoting bridge member is pivotable between a deployed position and a stowed position. A second hinge assembly pivotally couples the second pivoting bridge member to the center base section. A fourth plurality of electrical power contacts are disposed within the second pivoting bridge member, wherein the second plurality of electrical power contacts is operable to electrically couple the first plurality of electrical power contacts to the fourth plurality of electrical power contacts when the second pivoting bridge member is in the deployed position and further wherein the second plurality of electrical power contacts is configured to be electrically isolated from the fourth plurality of electrical contacts when the second pivoting bridge member is in the stowed position.

### BRIEF DESCRIPTION OF THE DRAWINGS

The invention may take form in various components and arrangements of components, and in various steps and arrangements of steps. The drawings are only for purposes of illustrating preferred embodiments and are not to be construed as limiting the invention.

FIG. 1 is an isometric view of a night vision assembly in accordance with an exemplary embodiment of the present disclosure.

FIG. 2A is top plan view of the night vision assembly appearing in FIG. 1 wherein the two night vision monoculars are parallel to each other to provide a standard field of view.

FIG. 2B is top plan view of the night vision assembly appearing in FIG. 1 wherein the two night vision monoculars are angled outwardly in the viewing direction by a first angle to provide a first increased horizontal field of view relative to the standard field of view.

FIG. 2C is top plan view of the night vision assembly appearing in FIG. 1 wherein the two night vision monoculars are angled outwardly in the viewing direction by a second angle greater than the first angle to provide an second increased horizontal field of view which is greater than the first horizontal field of view.

FIG. 3 is an isometric view of the night vision assembly shown in FIG. 1 attached to a helmet via a helmet mount assembly, with the night vision assembly appearing in the deployed, i.e., operable or viewing, position.

FIG. 4 is an isometric view of the night vision assembly shown in FIG. 1 attached to a helmet via a helmet mount assembly, with the night vision assembly appearing flipped up to an intermediate stowed position.

FIG. 5 is an isometric view of the night vision assembly shown in FIG. 1 attached to a helmet via a helmet mount assembly, with the night vision assembly appearing in the fully stowed position, wherein the night vision assemblies have been rotatably flattened against the helmet/helmet mount assembly, thereby reducing neck strain.

FIG. 6 is an isometric view of the night vision assembly shown in FIG. 1, wherein the right night vision monocular assembly is in the pivoted position and the left night vision monocular assembly is in the viewing position.

FIG. 7 is an isometric view of the night vision assembly shown in FIG. 1, illustrating the manner of attachment of the right night vision monocular assembly to the powered bridge assembly, with a like interface provided for the left night vision monocular assembly. The left and right interface shoes provides both mechanical attachment and “x” axis power transfer to the respective night vision monocular device.

FIG. 8 is an isometric exploded view of the powered bridge assembly taken generally from the bottom.

FIG. 9 is an isometric exploded view of the night vision monocular assembly. The left and right night vision monocular assemblies are identical except that the night vision monocular pivot assembly (see FIG. 10) is rotated 180 degrees.

FIG. 10 is an isometric exploded view of the night vision monocular pivot assembly.

FIG. 11A is a fragmentary isometric view of the firearm having a powered weapon mount operable to receive a night vision monocular assembly when it is detached from the powered bridge assembly.

FIG. 11B is a fragmentary isometric view of the firearm and powered weapon mount appearing in FIG. 11A, with a night vision monocular assembly detachably mounted to the powered weapon mount, which is shown in the deployed or viewing position.

### DETAILED DESCRIPTION OF THE PREFERRED EMBODIMENT(S)

Reference will now be made in detail to presently preferred embodiments of the invention, one or more examples of which are illustrated in the accompanying drawings. Each example is provided by way of explanation of the invention, not limitation of the invention, which may be embodied in various forms. Therefore, specific structural and functional details disclosed herein are not to be interpreted as limiting but merely as a basis for the claims and as a representative basis for teaching one skilled in the art to variously employ the present inventive concept in virtually any appropriately detailed structure. Further, the terms and phrases used herein are not intended to be limiting but rather to provide an understandable description of the present development. In fact, it will be apparent to those skilled in the art that modifications and variations can be made in the present invention without departing from the scope or spirit thereof. For instance, features illustrated or described as part of one embodiment may be used on another embodiment to yield a still further embodiment. Thus, it is intended that the present invention cover such modifications and variations as come within the scope of the appended claims and their equivalents.

The terms “a” or “an,” as used herein, are defined as one or more than one. The term “another,” as used herein, is defined as at least a second or more. The terms “including” and/or “having” as used herein, are defined as comprising (i.e., open transition). The terms “attached,” “coupled,” “operatively coupled,” or the like as used herein are defined as indirectly or directly connected.

As used in this application, the terms “front,” “rear,” “upper,” “lower,” “upwardly,” “downwardly,” “left,” “right,” and other orientation descriptors are intended to facilitate the description of the exemplary embodiment(s) of the present invention, and are not intended to limit the structure thereof to any particular position or orientation.

All numbers herein are assumed to be modified by the term “about,” unless stated otherwise. The recitation of numerical ranges by endpoints includes all numbers subsumed within that range (e.g., 1 to 5 includes 1, 1.5, 2, 2.75, 3, 3.80, 4, and 5).

Referring now to the drawings, an articulating, modular night vision assembly 100 includes a powered bridge assembly 104 and left and right night vision monocular assemblies 300. The powered bridge assembly 104 includes a center or base section 108. A hot shoe power interface assembly 112 is disposed on an upper surface of the powered bridge base 108.

The hot shoe power interface assembly 112 includes an insulator block 116 having a center opening 120 and 4 corner openings 124. A hot shoe frame 132 includes a center opening 136 and 4 corner bosses 140 which are seated within 4 respective counterbores 128 in the insulator block 116. Hot shoe electrical power contacts 144 extend through corresponding openings in the insulator block 116 and the center opening 136 in the hot shoe frame 132. In the illustrated embodiment, 4 power contacts 144 are provided, i.e., positive and negative contacts for the right monocular assembly 300 and positive and negative contacts for the left monocular assembly 300. A sealing ring 148 is seated within an annular groove 150 to seal against entry of moisture or environmental contamination. Four fasteners 152 pass through clearance openings in the bosses 140 and engage the aligned bores 124 in the insulator block 116.

The center base section 108 is coupled to left and right folding or pivoting bridge members 200 via left and right pivot hinge assemblies 276. The center base section 108 includes left and right pairs of opposing hinge knuckles 156, each having an opening 160 aligned with a pivot axis 162. The left and right folding bridge members 200 each include a hinge knuckle 208 positioned between the hinge knuckles 156 of the respective side of the center base section 108. Each hinge knuckle 208 has a bore 212 extending along the pivot axis 162.

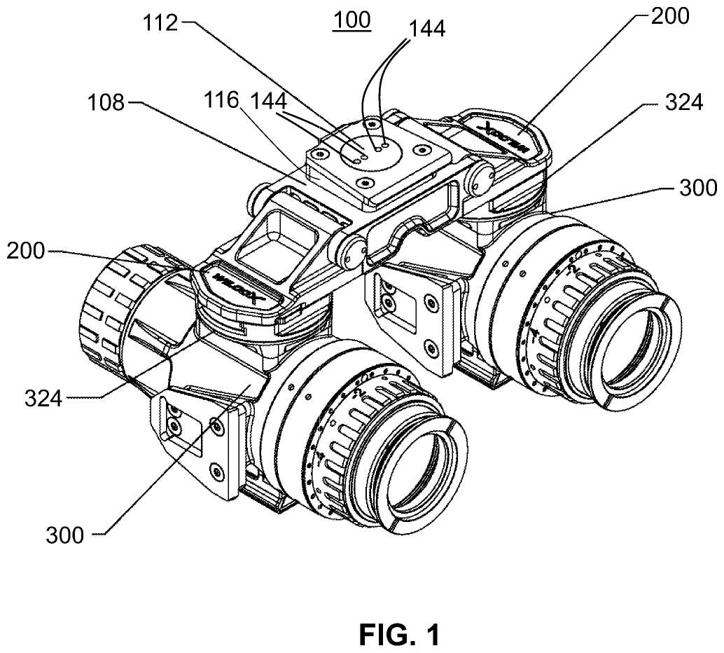

For each hinge assembly 276, a pair of detent members 164 is captured between the center base section 108 and the respective hinge knuckle 208. The detent members 164 are partially received within openings 178 formed in the left and right sidewalls of the section 108 and are biased toward engagement with the hinge knuckle 208 via captured detent bias springs 168. The knuckle 208 includes a detent slot 214 extending parallel to the pivot axis 162. The detent slot 214 is rotationally aligned with the detent members 164 when the corresponding folding bridge member 200 is in the deployed position as shown in FIG. 1.

Each pivot hinge assembly 276 includes a pivot pin or rod 280 passing through the aligned bores in the hinge knuckles 156 and 208. Each pivot rod 280 has an enlarged diameter head 284 at one end and a threaded end 288 at the opposite end. A threaded cap 292 engages the threaded end 288. For each hinge assembly 276, a pair of tensioning washers 296 are disposed on opposite sides of each hinge knuckle 208, intermediate the hinge knuckle 208 and the corresponding one of the hinge knuckles 156.

Spring loaded positive and negative power contacts 172 (e.g., telescoping pogo pins) on the right folding bridge member 200 are in electrical communication with a first pair of the power contacts 144 on the hot shoe power interface 112. Likewise, spring loaded positive and negative power contacts 172 on the left folding bridge member 200 are in electrical communication with a second pair of the power contacts 144 on the hot shoe power interface 112. The contacts 172 extend in transverse bores 176 in the bridge center section 108 and pass through insulator sleeves 180. Sealing rings 184 are provided around the insulator sleeves 180 to prevent entry of moisture or other contamination.

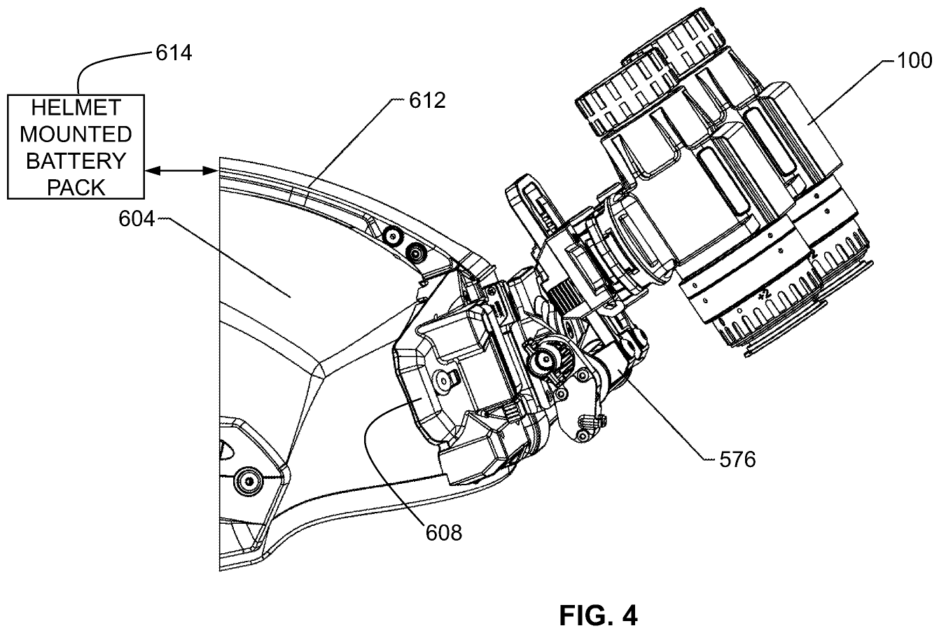

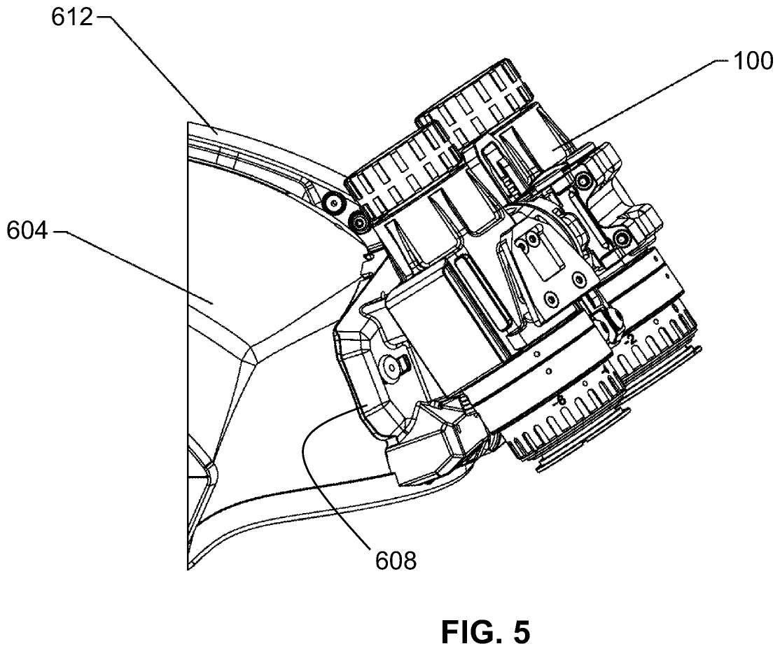

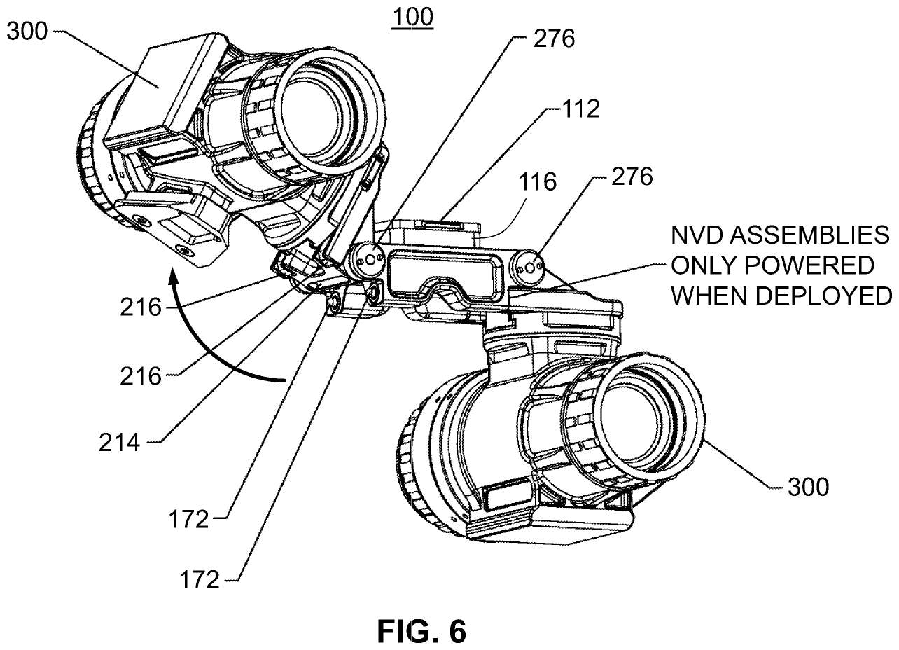

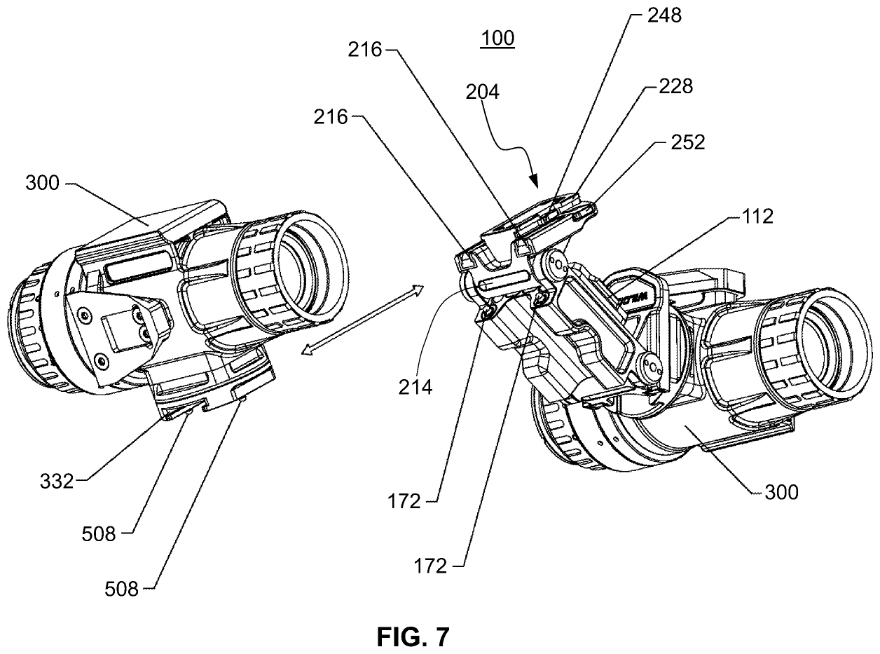

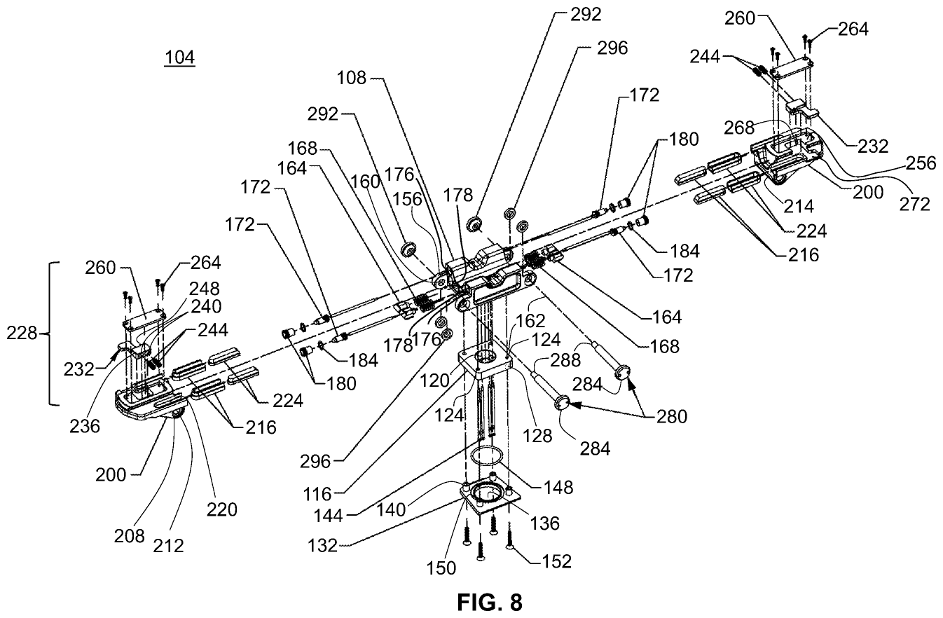

Each of the left and right folding bridge sections 200 include a transverse T slide assembly 204. A pair of elongated positive and negative pair of power transfer plates 216 are disposed in channels 220 formed in each of the right and left folding bridge members 200. Each of the power transfer plates 216 defines a channel receiving an insulator 224 formed of a dielectric material. The power transfer plates 216 contact the respective power contacts 172 when the corresponding folding bridge member 200 is in the deployed position to electrically couple the center section 108 with the folding bridge members 200. However, as best seen in FIGS. 6 and 7, when the folding bridge members 200 are pivoted to the stowed position wherein the monocular assemblies 300 are flattened to the low profile, stowed position as shown in FIG. 5, the power transfer plates 216 are moved out of contact with the respective pins 172 thereby shutting off power to the monocular assemblies 300 and conserving the power supply 614. Shutting off the monocular assemblies 300 also eliminates the emission of light which can be detected in low or no light conditions (see FIG. 4).

Each of the left and right folding bridge sections 200 include a slide lock assembly 228. Each slide lock assembly 228 includes slide lock member 232. The slide lock member, in turn, includes a main body portion 236 having one or more blind bores 240 each receiving a spring or other resilient biasing member 244.

The main body 236 further includes one or more locking teeth 248 which engage with a series of slide lock grooves 336 in a T-shaped channel 332 of an upper pivot plate 328 of a night vision device pivot assembly 324, as will be described in greater detail below. The slide lock member 232 further includes a slide lock release portion 252 extending from the main body 236. It will be recognized that the T-shaped channel 332 could be replaced with other interlocking configuration such as a dovetail joint, tongue and groove joint, or other interlocking arrangement.

The slide lock assembly 228 has an overall cross-sectional shape that is complementary with the T-shaped channel 332 to allow slidable and removable attachment therebetween. The position of the slide lock assembly 228 in relation to the pivoting arm 200 allows a transverse or lateral adjustment (i.e., along the X-axis indicated in the drawings) of the night vision monocular assemblies 300. In this manner, the transverse or lateral position of the left and right night vision monocular assemblies 300 can be adjusted to align each of the left and right night vision monocular assemblies 300 with the respective eye of the wearer and set a desired interpupillary distance between the monocular assemblies 300.

The lower surface of the slide lock assembly 228 has a cover recess 256 which has an area and depth configured to accommodate a slide lock cover plate 260 such that the cover plate 260 sits flush with the lower surface of the slide lock assembly 228. The cover plate 260 is secured with 4 threaded fasteners 264 which pass through clearance openings at the corners of the cover plate and threadably engage aligned fastener openings in the cover recess 256.

A slide lock recess 268 is formed within the cover recess 256 and receives the main body 236 and the springs 244. A lock release side opening 272 provides a passage between the slide lock recess 268 to allow the lock release member 252 to protrude therethrough. In this manner, the lock release member 252 can be manually depressed by the user against the urging of the springs 244 which, in turn, disengages the one or more locking teeth 248 from the slide lock grooves 336 to allow sliding movement of the slide lock assembly 228 in relation to the T-shaped channel 332. Once the desired position is achieved, the lock release member 252 is released and the springs 244 urge the one or more locking teeth 248 into engagement with the series of locking grooves 336 to secure the slide lock assembly 228 in place at a desired position. In the illustrated embodiment, the lock release member 252 is at least partially offset from the main body 236 in the vertical or “Z” direction.

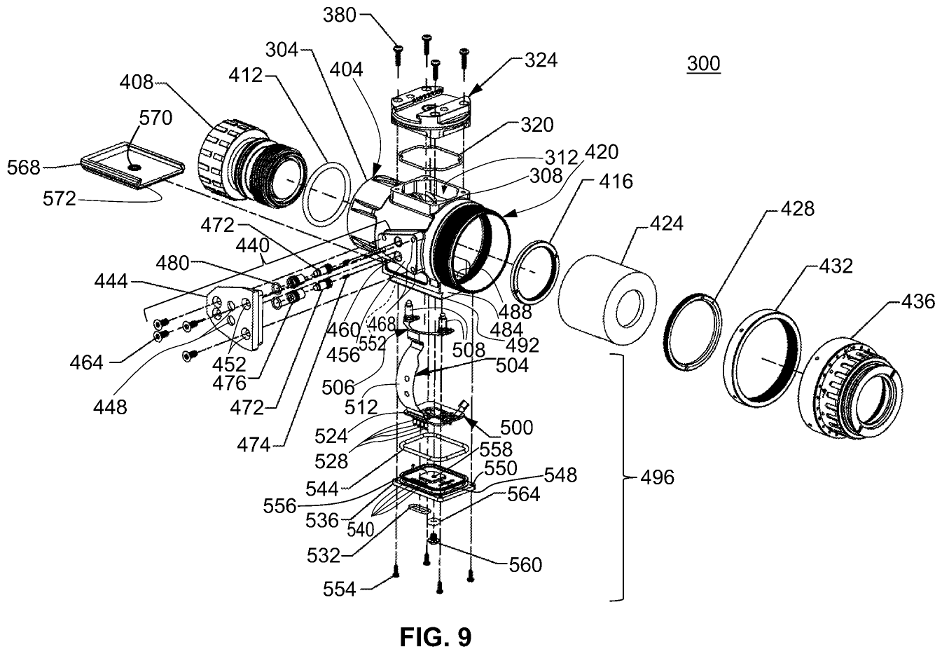

As best seen in FIG. 9, referring now to the left and right night vision monocular assemblies 300, each monocular assembly 300 includes a main housing 304. A pivot assembly mounting boss 308 is disposed on the housing 304 upper surface and extends upwardly therefrom. The pivot assembly mounting boss 308 bounds an opening 312 in the main housing shell 304. Four bores 316 are positioned in the corners of the boss 308, each bore threadably engaging a threaded fastener 380 to secure a night vision device pivot assembly 324 to the upper surface of the housing 304. A sealing ring or gasket 320 provides a sealing interference between the pivot assembly mounting boss 308 and the night vision device pivot assembly 324. The left and right night vision assemblies 300 are identical, except that the night vision device pivot assembly 324 of the left night vision assembly 300 is rotated 180 degrees about a vertical axis with respect to the night vision device pivot assembly 324 of the right night vision assembly 300.

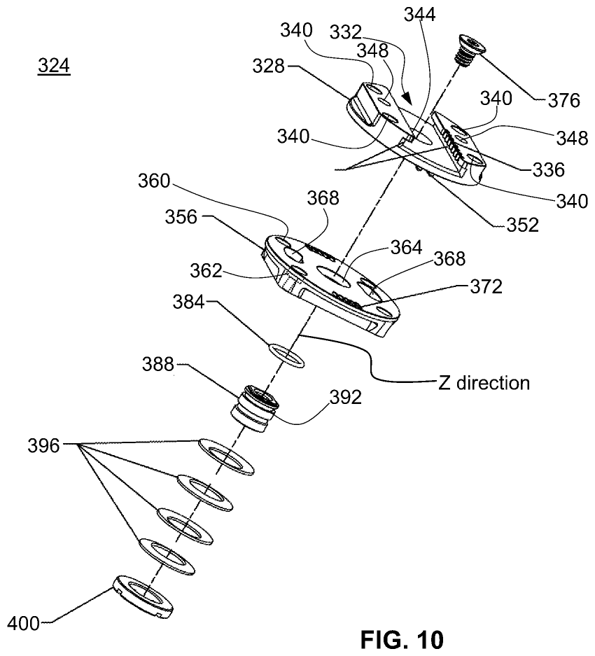

As best seen in FIG. 10, referring now to the night vision device pivot assembly 324, the night vision device pivot assembly includes an upper plate 328 which pivots or rotates, i.e., about an axis extending in the “Z” direction, in relation to a lower pivot plate 356. The upper pivot plate 328 includes the T-channel 332 on its upper surface. The upper pivot plate 328 includes 4 corner pass-through openings 340 which provide clearance for the heads of fasteners 380 (see FIG. 9) to pass therethrough.

A central opening 344 receives a threaded central pivot fastener 376 therethrough. In embodiments, the central opening 344 includes a countersink to allow the head of the pivot fastener 376 to lie flush with or below the base surface of the T-shaped channel 332. A pair of power contact openings 348 are configured to allow positive and negative power contacts 508 (see FIG. 9) to extend therethrough as a means of electrically coupling the associated and attached night vision monocular assembly 300 to a power source.

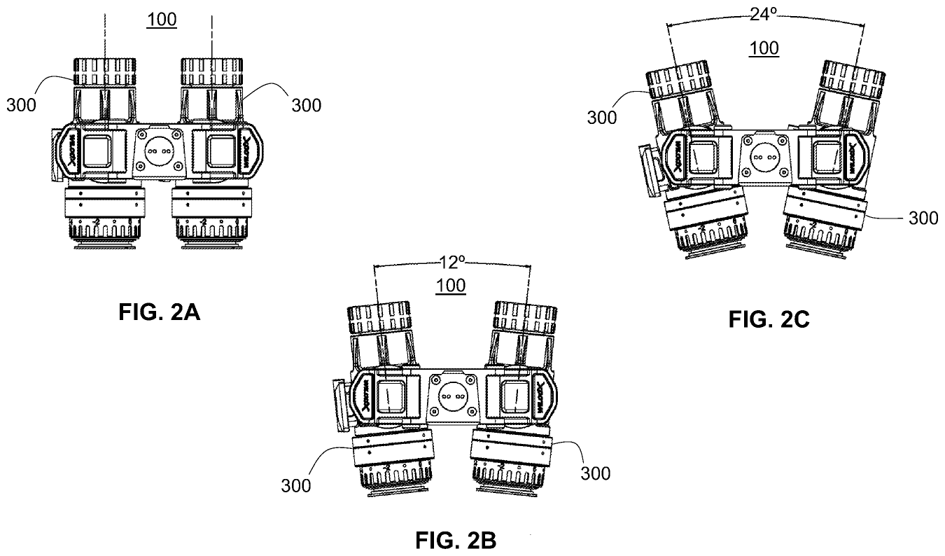

Detent pillars or pins 352 on the bottom surface of the upper pivot plate 328, each of which runs in a respective arcuate detent slot 372 formed on the upper surface of the lower pivot plate 356. The detent slots 372 limit the degree of rotation of the upper pivot plate 328 in relation to the lower pivot plate 356. The detent slots 372 also have a series of detent stop features to provide precise retention of the upper pivot plate 328 at a plurality of predefined angular positions with respect to the lower pivot plate 356. In embodiments, the predefined angular positions are defined by scalloped notches in the detent slots 372. In preferred embodiments, there are 5 scalloped notches, each spaced apart by 6 degrees of rotation to allow precise rotational positioning of the upper pivot plate 328 in relation to the lower pivot plate 356 at one of five detent stops. In preferred embodiments, the scalloped notches are configured to allow angular positioning of the upper pivot plate 328 in relation to the lower pivot plate 356 at −12 degrees, −6 degrees, 0 degrees, +6 degrees, and +12 degrees in relation to the optical axis of the attached night vision monocular assembly 300 when it is at the center or zero degree position. In this manner, the unit 100 can be configured to have selectable relative angles between an attached pair of night vision monocular assemblies 300, including 0 degrees (see FIG. 2A), 12 degrees (see FIG. 2B), and 24 degrees (see FIG. 2C). This allows adjustment of the horizontal field of view of the night vision assembly 100.

The lower pivot plate 356 includes 4 corner clearance bores 360 for receiving the shaft portion of the threaded fasteners 380 (see FIG. 9). Each bore 360 further includes a counterbore 362 sized to receive the head of the fasteners 380 so that the head of the fasteners 380 are flush with or sit below the upper surface of the lower pivot plate 356. A threaded pivot post 388 is received within a central opening 364 in the lower pivot plate 356.

Power contact openings 368 are formed in the lower pivot plate 356 to allow the contacts 508 (see FIG. 9) to pass therethrough. The power contact openings 368 are elongated and arcuate or otherwise enlarged to permit rotational movement between the upper pivot plate 328 and the lower pivot plate 356.

The central pivot fastener 376 engages an internally threaded pivot post 388. A sealing ring 384 is received within a groove 392 formed on the threaded post 388 to prevent entry of moisture or other environmental contamination.

A stack of Belleville disc springs or conical spring washers 396 are disposed about the threaded pivot post 388 and are retained thereon via a threaded tensioning retainer rings 400 engaging the lower end of the threaded pivot post 388 to maintain tension between the fastener 376 and the threaded pivot post 388.

The housing 304 has a distal end 404 (with respect to the user's eye) which receives an objective lens assembly 408. A sealing ring 412 is disposed between the objective lens assembly 408 and the housing distal end 404 to prevent entry of moisture or other external contamination into the interior of the housing 304. An objective lens retainer or stop ring 416 retains or limits travel of the objective lens assembly 408.

The housing 304 further has a proximal end 420 opposite distal end 404. An image intensifier tube 424 is received within the housing 304. The objective lens assembly 408 is configured to focus incoming photons received from the surroundings onto a photocathode of the image intensifier tube 424 which emits an electron signal which is amplified and converted to a human-viewable image using a phosphor screen as would be understood by persons skilled in the art. A tube retainer ring 428 secures the image intensifier tube 424 within the housing 304. A lock ring 432 is disposed intermediate the housing 304 proximal end 420 and an eyepiece lens assembly 436.

A side (left side in the illustrated exemplary embodiment) of the housing 304 includes a weapon hot shoe assembly 440. The weapon hot shoe assembly 440 includes a weapon hot shoe plate 444 which has a pair of openings 448 for receiving positive and negative electrical power contacts 472. The weapon hot shoe plate 444 is secured to a weapon hot shoe boss 456 which protrudes from the sidewall of the housing 304. Four threaded fasteners 464 pass through respective clearance openings 452 in the weapon hot shoe plate 444 and threadably engage respective fastener openings 468 in the weapon hot shoe boss 456. Each of the four clearance openings 452 have a countersink or counterbore to allow the head of the fasteners 464 to be flush with or lower than the outward facing surface of the weapon hot shoe plate 444. A pair of power contact openings 460 in the weapon hot shoe boss 456 are aligned with the pair of power contact openings 448 in the weapon hot shoe plate 444.

The positive and negative power contacts 472 are received within insulator sleeves 476, which in turn are received within the openings 460 in the weapon hot shoe boss 456. Sealing rings 480 are disposed intermediate the insulator sleeves 476 and the inward facing surface of the weapon hot shoe plate 444 about the openings 448 to prevent entry of moisture or environmental contamination therethrough. Power contact biasing springs 474 urge the power contacts 472 outward to maintain electrical contact and prevent the contact from losing connection due to vibration or movement. The power contacts 472 are in electrical communication with the power contact circuit board flex assembly 504.

The bottom surface of the housing 304 has a lower power contact boss 484 having an opening 488 into the interior of the housing 304. Longitudinally extending interlocking protrusions 492, e.g., dovetail protrusions in the illustrated embodiment, are formed on opposing sides of the lower power contact boss 484. The interlocking protrusions 492 slidably engage a complementary pair of opposing interlocking recesses or grooves 572, e.g., dovetail socket recesses, which are formed on a blanking cover 568. It will be recognized that the dovetail configuration could be replaced with another interlocking configuration such as a T-slot joint, tongue and groove joint, or other interlocking arrangement.

A power circuit assembly 496 is received within the housing 304 and is operably coupled to the image intensifier 424 to provide electrical power thereto via any of the power connectors as described herein. A power circuit assembly 496 includes a flexible circuit board 512 to allow the circuitry within the housing 304 to extend around the image intensifier tube 424. The flexible circuit board 512 comprises circuit components such as connector elements and electrically conductive traces on a circuit substrate formed of a flexible material such as a flexible polymer film material.

The power circuit assembly 496 includes a power contact circuit board assembly 500 and a power contact circuit board flex assembly 504. An upper portion 506 has positive and negative power contacts 508 which pass through the power contact openings 368 in the lower pivot plate 356 and the power contact openings 348 in the upper pivot plate 328.

The power contact circuit board flex assembly 504 includes the flexible circuit board 512, which extends 180 degrees around the intensifier tube 424. The power contact circuit board subassembly 500 includes a circuit board 524 having four power contacts 528 thereon. In embodiments, the contacts 528 are spring-loaded contacts, e.g., pogo contact pins. The pins/contacts 528 extend through openings 540 formed in a lower power contact cover 536. A sealing ring 532 is disposed around the openings 540 to prevent entry of moisture or external contamination into the interior of the housing 304.

The power contacts 528 and openings 540 cooperate to define an electrical connector assembly for providing power to operate the unit 300 using an alternative power supply (not shown). In embodiments, the alternative power supply is a battery pack (not shown) which has a mounting feature such as dovetail recesses which are compatible with the dovetail mounting rails 492 and electrical contacts which engage the contacts 528. In this manner, a battery pack may be attached to the lower power contact boss 484 in place of the blanking cover 568 to power the monocular assembly 300. In other embodiments, power contacts 528 and openings 540 may be adapted to receive electrical power into the monocular assembly 300 via power cable as a means of powering the night vision monocular assembly. In still further embodiments, the power contacts 528 may be configured to send power that is input to the monocular assembly 300, e.g., via the hot shoe power interface 112 or the weapon hot shoe 444, to power another device, such as an accessory that is attached to the lower power contact boss 484 in place of the blanking cover 568.

A sealing ring 544 is seated within an annular groove 548 to provide a sealing engagement between the lower power contact cover 536 and the lower power contact boss 484. Four clearance openings 550 are disposed at the corners of the lower power contact cover 536. Fasteners 554 pass through the openings 550 and engage aligned fastener openings 552 in the lower power contact boss 484.

An upstanding boss or area of increased thickness 556 is formed on the inner surface of the lower power contact cover 536 and has a purge opening 558 therein. The purge opening 558 is used to flush the unit 300 with nitrogen or other inert gas to remove oxygen, moisture, or other contaminants. After purging, the opening 558 is plugged with a purge screw 560 and sealed with a sealing ring 564. The purge opening 558 has a counterbore (not shown) on the lower or outward facing surface thereof to allow the head of the purge screw to be recessed with respect to the outward facing surface of the outward facing surface of the lower power contact cover plate 536. The blanking cover 568 is preferably slidably and detachably received over the lower power contact cover 536 as described above when the monocular night vision device assemblies 300 are used in connection with the night vision device assembly 100. The blanking cover 568 is removable when it is desired to use a direct cabled connection to power the monocular assemblies 300. The inward facing surface of the blanking cover 568 includes a protruding detent 570 which engages the counterbore formed in the purge opening 558.

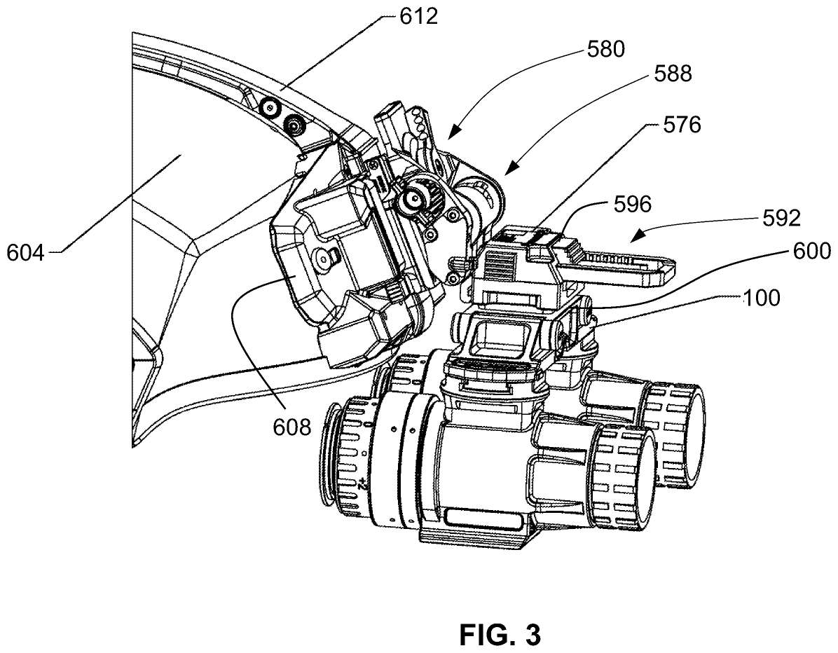

An exemplary helmet mount assembly 576 is illustrated in FIGS. 3-5. The helmet mount assembly 576 includes a helmet interface arm portion 580 which is pivotally attached to a slide carriage arm 592 via a pivot mechanism 588. The interface arm portion 580 may include a vertical adjustment mechanism to raise and lower the position of the unit 100 in relation to the eyes or line of sight of the user. The carriage arm 592 include a slide carriage assembly 596, which is slidable fore and aft, to position the unit 100 in relation to a focal length of the eyes of the user. The slide carriage assembly 596 includes a hot shoe receiver 600 which detachably engages the hot shoe interface 112. The hot shoe receiver 600 has electrical contacts (not shown) that provide power to the unit 100 via the electrical contacts 144 on the hot shoe power interface 112. In embodiments, the helmet mount assembly 576 may be a WILCOX™ G-24 Xe powered helmet mount assembly (Wilcox Industries Corp., Newington, NH).

A helmet 604, such as a military field helmet, tactical helmet, or the like, includes a front shroud 608. The illustrated helmet 604 is depicted with a powered helmet accessory mounting system 612. In embodiments, the powered helmet accessory mounting system 612 may be as described in commonly-owned U.S. patent application Ser. No. 18/500,657 filed Nov. 2, 2023, the entire contents of which are incorporated herein by reference in its entirety.

The powered helmet accessory mounting system 612 includes a battery pack 614 which is in electrical communication with the shroud 608 via the powered helmet accessory mounting system 612. The shroud 608, in turn, is in electrical communication with the helmet mount assembly 576, e.g., via mating electrical contacts. It will be recognized that other configurations for supplying electrical power from a helmet or body worn battery pack to the unit 100 are contemplated.

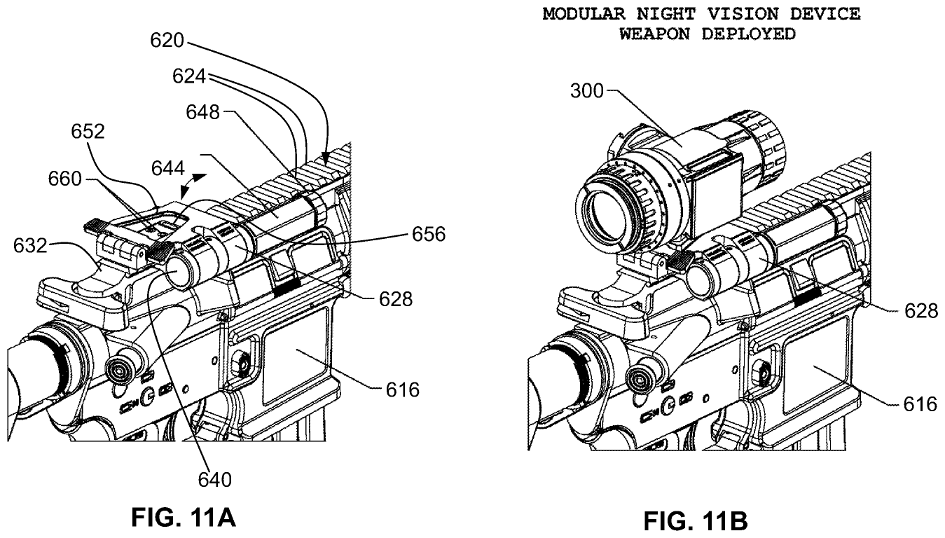

Referring now to FIGS. 11A and 11B, there is shown an exemplary weapon 616, such as a rifle, having a weapon accessory rail 620. The weapon accessory rail 620 may be a Picatinny rail, such as a MIL-STD-1913 or STANAG 4694 mounting platform having a series of transverse recoil grooves 624.

A powered weapon mount 628 includes a base 632 having a rail clamp for detachable engaging the rail 620. The base 632 is pivotally attached to a pivoting accessory interface 652 via a hinge assembly 640. In embodiments, the hinge includes a battery compartment 644 and a battery cap 648 providing access to the battery compartment 644. The hinge allows the night vision assembly 300 to be pivoted out of the way when not in use. In alternative embodiments, not shown, when the weapon accessory rail 620 is a powered accessory rail, the battery compartment 644 can be omitted and the powered rail system may be used to power the night vision assembly 300.

The pivoting accessory interface 652 includes a powered mounting interface which mechanically attaches the night vision assembly 300 to the powered weapon mount 628 via the weapon hot shoe 444. Mechanical and electrical communication between the weapon hot shoe weapon 444 and the weapon hot shoe power contacts 472 is made via a shoe receiver 656 and power contacts 660, respectively, on the powered weapon mount 628.

The invention has been described with reference to the preferred embodiment. Modifications and alterations will occur to others upon a reading and understanding of the preceding detailed description. It is intended that the invention be construed as including all such modifications and alterations insofar as they come within the scope of the appended claims or the equivalents thereof.

Having thus described the preferred embodiments, the invention is now claimed to be:

1. A monocular assembly comprising:
a housing having an interior;
an objective lens assembly coupled to a distal end of the housing;
an eyepiece assembly coupled to a proximal end of the housing;
an image intensifier tube disposed within the housing;
a power contact circuit board flex assembly disposed within the housing, the power contact circuit board flex assembly comprising:
a flexible circuit board;
a first plurality of power contacts in electrical communication with the flexible circuit board and disposed at a first angular position on the housing;
a second plurality of power contacts in electrical communication with the flexible circuit board and disposed at a second angular position on the housing;
a third plurality of power contacts in electrical communication with the flexible circuit board and disposed at a third angular position on the housing;
each of the first, second, and third plurality of power contacts in electrical communication with the image intensifier tube; and
wherein the flexible circuit board extends around the image intensifier tube within the interior of the housing.

2. The monocular assembly as claimed in claim 1, further comprising:
a lower power contact cover with at a plurality of openings through which the third plurality of power contacts extend.

3. The monocular assembly as claimed in claim 1, further comprising:
an opening in the housing;
a pivot assembly covering the opening in the housing opening, the pivot assembly comprising:
a lower pivot plate affixed to the housing; and
an upper pivot plate secured to the lower pivot plate, the upper pivot plate rotatable in relation to the lower pivot plate.

4. The monocular assembly as claimed in claim 3, wherein the lower pivot plate comprises a plurality of detent slots and the upper pivot plate comprises at least one detent pillar positioned and sized to be caught by any of the plurality of detent slots such that the rotation of the upper pivot plate is stopped at the catching of the at least one detent pillar by one of the plurality of detent slots.

5. The monocular assembly as claimed in claim 4, wherein the plurality of detent slots includes five detent slots spaced apart by 6 degrees of rotation, allowing selective angular positioning of the upper pivot plate with relation to the lower pivot plate at an angle of negative 12 degrees, negative 6 degrees, 0 degrees, positive 6 degrees, and positive 12 degrees.

6. The monocular assembly as claimed in claim 3, wherein the first plurality of power contacts comprise positive and negative power contacts each of which extend through an aligned power contact opening in the lower pivot plate and aligned power contact opening in the upper pivot plate.

7. The monocular assembly as claimed in claim 6, wherein the aligned power contact openings in the lower pivot plate define curved slots in which individual ones of the first plurality of power contacts run during rotational movement between the upper and lower pivot plates.

8. The monocular assembly as claimed in claim 3, further comprising a pivot assembly mounting boss extending from the housing and surrounding the opening in the housing, wherein the lower pivot plate is affixed to the pivot assembly mounting boss.

9. The monocular assembly as claimed in claim 3, further comprising:
a weapon hot shoe disposed at the second angular position on the housing, the weapon hot shoe having a weapon hot shoe plate portion;
a plurality of bores extending through the weapon hot shoe; and
a plurality of power contact pins received within the plurality of bores, the plurality of power contact pins in electrical communication with the second plurality of power contacts and protruding from the weapon hot shoe plate portion.

10. The monocular assembly as claimed in claim 1, further comprising:
a weapon hot shoe disposed at the second angular position on the housing, the weapon hot shoe having a weapon hot shoe plate portion;
a plurality of bores extending through the weapon hot shoe; and
a plurality of power contact pins received within the plurality of bores, the plurality of power contact pins in electrical communication with the second plurality of power contacts and protruding from the weapon hot shoe plate portion.

11. The monocular assembly as claimed in claim 10, wherein the weapon hot shoe assembly further comprises a weapon hot shoe boss extending from the housing and wherein the weapon hot shoe plate is affixed to the weapon hot shoe boss.

12. The monocular assembly as claimed in claim 10, further comprising a powered weapon mount comprising:
a powered weapon mount base having a rail clamp for detachable engagement of a weapon rail; and
an accessory interface pivotally attached to the powered weapon mount base via a hinge assembly, the accessory interface comprising:
a shoe receiver designed for mechanical releasable communication with the weapon hot shoe plate of the weapon hot shoe assembly; and
a plurality of receiver power contacts in electrical communication with the second plurality of power contact pins when the shoe receiver and the weapon hot shoe plate are paired.

13. The monocular assembly as claimed in claim 1, further comprising:
a lower circuit board secured to the housing at the third angular position, the lower circuit board having said third plurality of power contacts thereon.

14. The monocular assembly as claimed in claim 13, further comprising:
a lower contact boss disposed on the housing at the third angular position, the lower contact boss defining a lower opening into the housing, the lower contact boss and longitudinally extending protrusions formed on opposing sides of the lower contact boss; and
a lower power contact cover covering the lower opening, the lower power contact cover having a plurality of apertures therethrough, the plurality of apertures receiving the third plurality of power contacts.

15. The monocular assembly as claimed in claim 14, further comprising:
a lower contact boss having longitudinally extending interlocking protrusions formed on opposing sides thereof;
a blanking cover having a pair of opposing longitudinally extending interlocking recesses that slidably engage with the longitudinally extending interlocking protrusions, the blanking cover configured to cover the third plurality of power contacts.

16. A powered bridge assembly, comprising:
a center base section having a hot shoe power interface operable to detachably couple to a helmet mount assembly;
a first plurality of electrical power contacts disposed within the center base section and electrically coupled to a second plurality of electrical power contacts disposed within the center base section, the first plurality of electrical contacts configured to receive power from the helmet mount assembly;
a first pivoting bridge member including a first slide lock assembly for detachably coupling a first monocular assembly, the first pivoting bridge member pivotable between a deployed position and a stowed position;
a first hinge assembly pivotally coupling the first pivoting bridge member to the center base section;
a third plurality of electrical power contacts disposed within the first pivoting bridge member, wherein the second plurality of electrical power contacts is operable to electrically couple the first plurality of electrical power contacts to the third plurality of electrical power contacts when the first pivoting bridge member is in the deployed position and further wherein the second plurality of electrical power contacts is configured to be electrically isolated from the third plurality of electrical contacts when the first pivoting bridge member is in the stowed position.

17. The powered bridge assembly as claimed in claim 16, further comprising the first monocular assembly detachably coupled to the first pivoting bridge member, the first monocular assembly comprising:
a housing having an interior;
an objective lens assembly coupled to a distal end of the housing;
an eyepiece assembly coupled to a proximal end of the housing;
an image intensifier tube disposed within the housing;
a power contact circuit board flex assembly disposed within the housing, the power contact circuit board flex assembly comprising:
a flexible circuit board;
a fourth plurality of power contacts in electrical communication with the flexible circuit board and disposed at a first angular position on the housing;
a fifth plurality of power contacts in electrical communication with the flexible circuit board and disposed at a second angular position on the housing;
a sixth plurality of power contacts in electrical communication with the flexible circuit board and disposed at a third angular position on the housing;
each of the fourth, fifth, and sixth plurality of power contacts in electrical communication with the image intensifier tube; and
wherein the flexible circuit board extends around the image intensifier tube within the interior of the housing.

18. The powered bridge assembly as claimed in claim 16, further comprising:
an opening in the housing;
a pivot assembly covering the opening in the housing opening, the pivot assembly comprising:
a lower pivot plate affixed to the housing; and
an upper pivot plate secured to the lower pivot plate, the upper pivot plate rotatable in relation to the lower pivot plate.

19. The powered bridge assembly as claimed in claim 18 wherein the first pivoting bridge member includes a slide lock assembly structured and operable to releasably couple with the upper pivot plate of the first monocular assembly.

20. The powered bridge assembly as claimed in claim 16, further comprising:
a second pivoting bridge member, the second pivoting bridge member including a second slide lock assembly for detachably coupling a second monocular assembly, the first pivoting bridge member pivotable between a deployed position and a stowed position;
a second hinge assembly pivotally coupling the second pivoting bridge member to the center base section;
a fourth plurality of electrical power contacts disposed within the second pivoting bridge member, wherein the second plurality of electrical power contacts is operable to electrically couple the first plurality of electrical power contacts to the fourth plurality of electrical power contacts when the second pivoting bridge member is in the deployed position and further wherein the second plurality of electrical power contacts is configured to be electrically isolated from the fourth plurality of electrical contacts when the second pivoting bridge member is in the stowed position.
